(19) United States
(12) Patent Application Publication
(10) Pub. No.: US 2025/0228110 A1
(43) Pub. Date: Jul. 10, 2025

(54) DISPLAY PANEL AND METHOD OF MANUFACTURING DISPLAY PANEL

(71) Applicants: Beijing BOE Technology Development Co., Ltd., Beijing (CN); BOE Technology Group Co., Ltd., Beijing (CN)

(72) Inventors: Dacheng Zhang, Beijing (CN); Chen Xu, Beijing (CN); Chao Pu, Beijing (CN)

(21) Appl. No.: 18/851,055

(22) PCT Filed: Nov. 17, 2023
(86) PCT No.: PCT/CN2023/132366

§ 371 Date: Sep. 25, 2024

(51) Int. Cl. H10K 59/80; H10K 59/122; H10K 59/38

(52) U.S. Cl. CPC H10K 59/879; H10K 59/122; H10K 59/38

(57) ABSTRACT

A display panel and a manufacturing method thereof. The display panel includes: a base substrate; and sub-pixels on the base substrate. Each sub-pixel includes: a light-emitting unit having first and second electrodes and a light-emitting layer; an encapsulation layer covering the light-emitting unit; a color filter on a side of the encapsulation layer away from the base substrate; and a micro lens on a side of the color filter away from the base substrate. A surface of the micro lens on a side away from the base substrate includes a central part and an edge part surrounding the central part, the central part is a flat surface parallel to the base substrate, the edge part is a curved surface protruding from an inside of the micro lens to an outside of the micro lens, and a roughness of the central part is greater than that of the edge part.

### TECHNICAL FIELD

The present disclosure relates to a field of display technology, and in particular, to a display panel and a method of manufacturing a display panel.

### BACKGROUND

With a development of display technology, requirements for display devices are becoming increasingly high. Display effects of the display devices are largely related to structures of display panels, but currently most display panels cannot meet the growing demand for display effects from users. Silicon-based OLED (Organic Light-Emitting Diode) is expected to become a preferred display solution for AR (Augmented Reality)/VR (Virtual Reality) due to its high contrast, high response speed, and high PPI (Pixels Per Inch) characteristics. However, a brightness of silicon-based OLED is currently difficult to meet the display requirements of AR/VR. In related art, in order to improve the display brightness of the silicon-based OLED, a micro lens is disposed on a light output side of the silicon-based OLED display device to increase the brightness of the display device. However, while using the micro lens to increase the brightness, the viewing angle characteristics are lost, the viewing angle and brightness requirements of AR/VR may not be met. In addition, most silicon-based OLEDs adopt a structure that combines white light with a color filter. The color filter made of an organic material has a micro dimension (such as 5 μm to 10 μm), and an overlapping height of adjacent color filters of different colors is relatively high, so as to form a bull horn, which affects the viewing angle and color uniformity of the silicon-based OLED display, thereby seriously affecting the display effect.

### SUMMARY

Embodiments of the present disclosure provide a display panel and a method of manufacturing a display panel.

According to an aspect of the present disclosure, a display panel is provided, including: a base substrate; and one or more sub-pixels on the base substrate, where each of the one or more sub-pixels includes: a light-emitting unit having a first electrode, a second electrode and a light-emitting layer between the first electrode and the second electrode, where the first electrode is located between the light-emitting layer and the base substrate; an encapsulation layer covering the light-emitting unit; a color filter on a side of the encapsulation layer away from the base substrate; and a micro lens on a side of the color filter away from the base substrate; where a surface of the micro lens on a side of the micro lens away from the base substrate includes a central part and an edge part surrounding the central part, the central part is a flat surface parallel to the base substrate, the edge part is a curved surface protruding from an inside of the micro lens to an outside of the micro lens, and a roughness of the central part is greater than a roughness of the edge part.

For example, the central part is continuous with the edge part.

For example, the micro lens has a groove on the side of the micro lens away from the base substrate, a bottom surface of the groove serves as the central part, and the central part is connected to the edge part through a sidewall of the groove.

For example, the central part has a first height relative to a bottom of the micro lens, the edge part has a second height relative to the bottom of the micro lens, and a ratio of the first height to the second height is in a range of 0.4 to 0.8.

For example, the display panel further includes a compensation micro lens between adjacent micro lenses, and a height of the compensation micro lens is less than a height of the central part of the micro lens.

For example, a roughness of a surface of the compensation micro lens on a side of the compensation micro lens away from the base substrate is less than the roughness of the central part.

For example, each of the central part and the edge part has a plurality of micro bumps, and the plurality of micro bumps of the central part have a height greater than a height of the plurality of micro bumps of the edge part, so that the roughness of the central part is greater than the roughness of the edge part.

For example, the plurality of micro bumps in a central region of the central part have a height greater than a height of the plurality of micro bumps in an edge region of the central part, so that a roughness of the central region of the central part is greater than a roughness of the edge region of the central part.

For example, the plurality of micro bumps of the central part have heights decreased from a center of the central part to an edge of the central part, so that the central part has roughnesses decreased from the center of the central part to the edge of the central part.

For example, a cross-section of one of the plurality of micro bumps of the central part in a direction perpendicular to the base substrate is in a shape of triangle, arc or rectangle.

For example, the plurality of micro bumps of the central part have a dimension in a range of 0.01 μm to 0.1 μm in a direction parallel to the base substrate, and the plurality of micro bumps of the central part have a dimension in a range of 5 nm to 50 nm in a direction perpendicular to the base substrate.

For example, a roughness of a central region of a surface of the color filter on the side of the color filter away from the base substrate is less than a roughness of an edge region of the surface of the color filter on the side of the color filter away from the base substrate.

For example, the surface of the color filter on the side of the color filter away from the base substrate has roughnesses increased from a center of the color filter to an edge of the color filter.

For example, the surface of the color filter on the side of the color filter away from the base substrate has micro bumps, the micro bumps in a central region of the color filter have a height less than 5 nm, and the micro bumps in an edge region of the color filter have a height in a range of 5 nm to 50 nm.

For example, a projection of a boundary between the central region of the color filter and the edge region of the color filter on the base substrate is within a projection of the edge part of the micro lens on the base substrate.

For example, each of the one or more sub-pixels further includes a pixel defining layer between the base substrate and the light-emitting layer of the light-emitting unit, and the pixel defining layer covers an edge of the first electrode of the light-emitting unit to define an opening region, such that a part of the first electrode of the light-emitting unit is exposed from the opening region.

For example, the edge part has a first projection in a direction perpendicular to the base substrate, and a part of the pixel defining layer covering the first electrode has a second projection in the direction perpendicular to the base substrate, and wherein a distance between an inner edge of the first projection and an outer edge of the first projection is greater than a distance between an inner edge of the second projection and an outer edge of the second projection.

For example, the one or more sub-pixels include a plurality of sub-pixels of a plurality of colors, and a color of each of the plurality of sub-pixels is defined by a color of the color filter of the each of the plurality of sub-pixels; and a ratio of an area of the central part of at least one of the plurality of sub-pixels having at least one color to an area of the opening region of the at least one of the plurality of sub-pixels is greater than a ratio of an area of the central part of any other one of the plurality of sub-pixels having any other color to an area of the opening region of the any other one of the plurality of sub-pixels.

For example, the plurality of sub-pixels of the plurality of colors include a first sub-pixel having a color filter of a first color, a second sub-pixel having a color filter of a second color, and a third sub-pixel having a color filter of a third color; and Src/Sr>Sgc/Sg>Sbc/Sb, where Sr represents an area of an opening region of the first sub-pixel, Sg represents an area of an opening region of the second sub-pixel, Sb represents an area of an opening region of the third sub-pixel, Src represents an area of the central part of the micro lens of the first sub-pixel, Srg represents an area of the central part of the micro lens of the second sub-pixel, and Srb represents an area of the central part of the micro lens of the third sub-pixel.

For example, Sr<Sg<Sb.

For example, the first color is red, the second color is green, and the third color is blue.

For example, for sub-pixels of same colors, a ratio of an area of the central part of any one of the sub-pixels of the same colors in a central region of the display panel to an area of the opening region of the any one of the sub-pixels of the same colors in the central region of the display panel is less than a ratio of an area of the central part of any one of the sub-pixels of the same colors in an edge region of the display panel to an area of the opening region of the any one of the sub-pixels of the same colors in the edge region of the display panel.

For example, among the sub-pixels of the same color, for the sub-pixels of the same colors, ratios of areas of the central parts of the sub-pixels of the same colors to areas of the opening regions of the sub-pixels of the same colors increase from a center of the display panel to an edge of the display panel.

For example, the central parts of the micro lenses of sub-pixels of different colors are located in a same plane.

For example, the micro lens of the sub-pixel is in contact with the color filter of the sub-pixel.

For example, bottom surfaces of the micro lenses of the sub-pixels of different colors have a height difference in the direction perpendicular to the base substrate; and the micro lens is in contact with the color filter through the bottom surface of the micro lens.

For example, the display panel further includes a planarization layer between the color filter of each of the one or more sub-pixels and the micro lens of each of the one or more sub-pixels.

For example, a photolithographic material is filled between adjacent micro lenses such that the edge part of the micro lens is covered by the photolithographic material.

For example, a refractive index of the photolithographic material is less than a refractive index of the micro lens.

For example, the refractive index of the photolithographic material is in a range of 1.3 to 1.6, and the refractive index of the micro lens is in a range of 1.6 to 2.1.

According to another aspect of the present disclosure, a method of manufacturing the display panel as described above is further provided, including: forming at least one light-emitting unit on a base substrate; forming an encapsulation layer covering the at least one light-emitting unit; forming a color filter on the encapsulation layer, where the color filter includes at least one color filter corresponding one-to-one with the at least one light-emitting unit; forming a micro lens layer on the color filter, where the micro lens layer includes at least one initial micro lens corresponding one-to-one with the at least one color filter, and a surface of the initial micro lens on a side of the initial micro lens away from the base substrate is a curved surface; forming a first photolithographic material layer on the micro lens layer, such that the first photolithographic material layer covers the at least one initial micro lens, and a surface of the first photolithographic material layer on a side of the first photolithographic material layer away from the base substrate is parallel to the base substrate; and removing a part of the micro lens layer and a part of the first photolithographic material layer by a dry etching process, so as to obtain a micro lens having a central part and an edge part.

For example, the removing a part of the micro lens layer and a part of the first photolithographic material layer by a dry etching process includes: performing dry etching on the micro lens layer and the first photolithographic material layer to obtain a micro lens having a central part and an edge part, where the central part is continuous with the edge part.

For example, the removing a part of the micro lens layer and a part of the first photolithographic material layer by a dry etching process includes: forming a groove in the first photolithographic material layer above each micro lens by a semi-mask process to obtain a patterned first photolithographic material layer; and performing dry etching on the patterned first photolithographic material layer and the micro lens layer to obtain a micro lens having a groove, where a bottom surface of the groove implemented as the central part, and the central part is connected to the edge part by a sidewall of the groove.

For example, the method further includes: before forming a micro lens layer on the color filter, forming a second photolithographic material layer on the color filter; and removing the second photolithographic material layer and a part of the color filter by a dry etching process, so as to planarize the color filter.

For example, the method further includes: forming a planarization layer on the color filter before forming a micro lens layer on the color filter.

For example, the method further includes: forming an inorganic layer on the planarization layer after forming the planarization layer on the color filter.

For example, the forming a micro lens layer includes: depositing an organic micro lens material on the color filter; removing a part of the micro lens material through exposure and development to obtain a plurality of columnar structures; transforming each columnar structure into a hemispherical structure through hot reflux process; and curing the hemispherical structure to obtain an initial micro lens.

According to another aspect of the present disclosure, another display panel is provided, including: a base substrate; one or more sub-pixels on the base substrate, where each of the one or more sub-pixels includes: a light-emitting unit having a first electrode, a second electrode and a light-emitting layer between the first electrode and the second electrode, where the first electrode is located between the light-emitting layer and the base substrate; and a micro lens on a side of the light-emitting unit away from the base substrate; where a surface of the micro lens on a side of the micro lens away from the base substrate includes a central part and an edge part surrounding the central part, the central part is a flat surface parallel to the base substrate, and the edge part is a curved surface protruding from an inside of the micro lens to an outside of the micro lens; and each of the central part and the edge part has a plurality of micro bumps, and the plurality of micro bumps of the central part have a height greater than a height of the plurality of micro bumps of the edge part.

For example, the plurality of micro bumps in a central region of the central part have a height greater than a height of the plurality of micro bumps in an edge region of the central part.

For example, the plurality of micro bumps of the central part have heights decreased from a center of the central part to an edge of the central part.

For example, a cross-section of one of the plurality of micro bumps of the central part in a direction perpendicular to the base substrate is in a shape of triangle, arc or rectangle.

For example, the plurality of micro bumps of the central part have a dimension in a range of 0.01 μm to 0.1 μm in a direction parallel to the base substrate, and the plurality of micro bumps of the central part have a dimension in a range of 5 nm to 50 nm in a direction perpendicular to the base substrate.

For example, each of the one or more sub-pixels further includes a color filter between the light-emitting unit and the micro lens, and where a surface of the color filter on a side of the color filter away from the base substrate has a plurality of micro bumps, and the plurality of micro bumps in a central region of the surface of the color filter have a height less than a height of the plurality of micro bumps in an edge region of the surface of the color filter.

For example, the plurality of micro bumps on the surface of the color filter on the side of the color filter away from the base substrate have heights increased from a center of the color filter to an edge of the color filter.

For example, the plurality of micro bumps in a central region of the surface of the color filter on the side of the color filter away from the base substrate have a height less than 5 nm, and the plurality of micro bumps in an edge region of the surface of the color filter on the side of the color filter away from the base substrate have a height in a range of 5 nm to 50 nm.

### BRIEF DESCRIPTION OF THE DRAWINGS

FIG. 1 shows a schematic structural diagram of a display panel according to an embodiment of the present disclosure.

FIG. 2 shows a schematic cross-sectional view of the micro lens shown in FIG. 1 according to an embodiment of the present disclosure.

FIG. 3 shows a schematic structural diagram of a display panel according to another embodiment of the present disclosure.

FIG. 4 shows a schematic cross-sectional view of the micro lens shown in FIG. 3 according to an embodiment of the present disclosure.

FIG. 5 shows a schematic structural diagram of a display panel according to another embodiment of the present disclosure.

FIG. 6 shows a schematic plan view of a display panel according to embodiments of the present disclosure.

FIG. 7A and FIG. 7B show enlarged views of schematic diagrams of a first sub-pixel SP1 and a fourth sub-pixel SP4 shown in FIG. 6, respectively.

FIG. 8 shows enlarged views of schematic diagrams of a first sub-pixel SP1, a second sub-pixel SP2 and a third sub-pixel SP3 shown in FIG. 6.

FIG. 9 shows a schematic cross-sectional view of the micro lens shown in FIG. 1 according to another embodiment of the present disclosure.

FIG. 10A shows a partial enlarged view of the display panel shown in FIG. 1 according to an embodiment of the present disclosure.

FIG. 10B shows a partial enlarged view of the display panel shown in FIG. 1 according to another embodiment of the present disclosure.

FIG. 10C shows a partial enlarged view of a surface of a color filter shown in FIG. 10B.

FIG. 10D shows a partial enlarged view of the display panel shown in FIG. 10B according to an embodiment of the present disclosure.

FIG. 10E shows a schematic plan view of a first projection and a second projection shown in FIG. 10D.

FIG. 11 shows a partial enlarged view of a display panel according to another embodiment of the present disclosure.

FIG. 12 shows a flowchart of a method of manufacturing a display panel according to embodiments of the present disclosure.

FIG. 13A to FIG. 13K show a process of manufacturing a display panel according to an embodiment of the present disclosure.

FIG. 14A to FIG. 14L show a process of manufacturing a display panel according to another embodiment of the present disclosure.

### DETAILED DESCRIPTION OF EMBODIMENTS

Although the present disclosure will be fully described with reference to accompanying drawings containing preferred embodiments of the present disclosure, prior to the description, it should be understood that those of ordinary skill in the art may modify the present disclosure described herein while obtaining the technical effects of the present disclosure. Therefore, it should be understood that the above description is a broad disclosure for those of ordinary skill in the art, and its content is not intended to limit exemplary embodiments described in the present disclosure.

In addition, in the detailed description below, for the sake of explanation, many specific details are described to provide a comprehensive understanding of the embodiments of the present disclosure. However, it is clear that one or more embodiments may also be implemented without these specific details. In other cases, well-known structures and devices are illustrated to simplify the accompanying drawings.

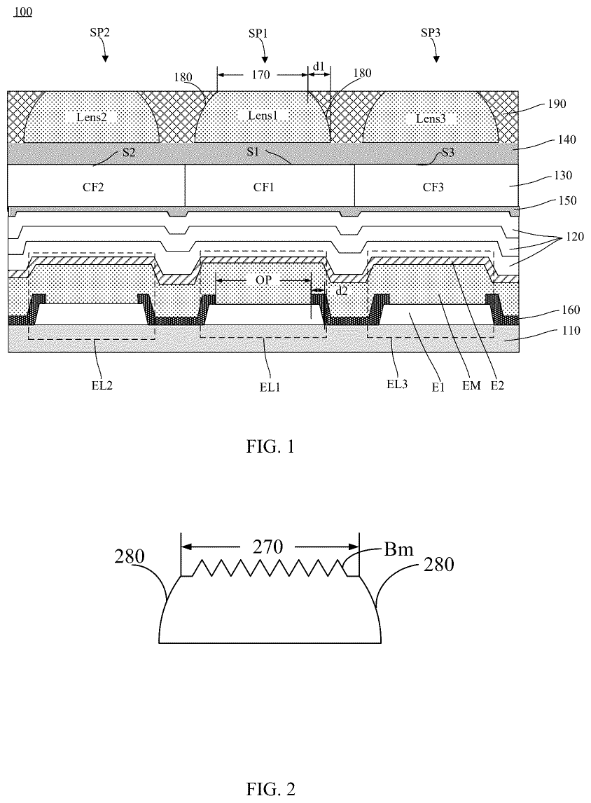

FIG. 1 shows a schematic structural diagram of a display panel according to an embodiment of the present disclosure.

As shown in FIG. 1, the display panel 100 includes a base substrate 110 and a plurality of sub-pixels SP1, SP2 and SP3 located on the base substrate 110. For the convenience of description, three sub-pixels SP1, SP2 and SP3 are shown in FIG. 1. However, embodiments of the present disclosure are not limited to this, the display panel may have any number of sub-pixels as desired. Each of the sub-pixels SP1, SP2 and SP3 includes a corresponding light-emitting unit, encapsulation layer, color filter and micro lens. For example, the sub-pixel SP1 includes a light-emitting unit EL1, an encapsulation layer 120, a color filter CF1 and a micro lens Lens1 arranged sequentially on the base substrate 110. Similarly, the sub-pixel SP2 includes a light-emitting unit EL2, an encapsulation layer 120, a color filter CF2 and a micro lens Lens2 stacked sequentially, and the sub-pixel SP3 includes a light-emitting unit EL3, an encapsulation layer 120, a color filter CF3 and a micro lens Lens3 stacked sequentially. As shown in FIG. 1, the respective encapsulation layers 120 of the sub-pixels SP1, SP2 and SP3 may be formed as a continuous layer covered by the color filters CF1, CF2 and CF3 of the sub-pixels SP1, SP2 and SP3. In some embodiments, the layer in which each color filter is located may be referred to as a color filter layer 130.

As shown in FIG. 1, the light-emitting units EL1, EL2 and EL3 are located on the base substrate 110. Each of the light-emitting units EL1, EL2 and EL3 has a first electrode E1, a second electrode E2, and a light-emitting layer EM located between the first electrode E1 and the second electrode E2. The first electrode E1 is located between the light-emitting layer EM and the base substrate 110.

The encapsulation layer 120 covers the light-emitting units EL1, EL2, and EL3. The encapsulation layer may be a multi-layer structure. In some embodiments, the encapsulation layer may include an organic and/or inorganic material, such as having a three-layer structure of SiN+Al₂O₃+SiN.

The color filter layer 130 is located on a side of the encapsulation layer 120 away from the base substrate 110. As shown in FIG. 1, the color filter layer 130 includes a first surface and a second surface (upper and lower surfaces shown in FIG. 1) opposite to each other in a direction perpendicular to the base substrate 110. A roughness of the first surface is greater than a roughness of the second surface. In other embodiments, each of the first surface and second surface of the color filter layer 130 has micro bumps.

In some embodiments, the color filter layer 130 may include the color filters CF1, CF2, and CF3 corresponding one-to-one with the light-emitting units EL1, EL2 and EL3. The composition and structure of the color filter may vary depending on a display mode. The color filters CF1, CF2, and CF3 may be arranged as bars, dots, triangles, mosaics, or other specific patterns (such as similar portrait or animal pattern). Bar and dot arrangements are generally used for large-sized and high-precision products. Triangle and mosaic arrangements are generally used for small-sized, and low-precision products. Chromaticity and transmittance are two major optical properties of the color filter, which mainly depend on the material of the color filter.

In some embodiments, the color filter layer 130 may include a first color filter CF1, a second color filter CF2 and a third color filter CF3. The first color filter CF1 may be a red color filter, the second color filter CF2 may be a green color filter, and the third color filter CF3 may be a blue color filter. A surface of the first color filter CF1 on a side of the first color filter CF1 away from the base substrate 110 is represented by S1, a surface of the second color filter CF2 on a side of the second color filter CF2 away from the base substrate 110 is represented by S2, and a surface of the third color filter CF3 on a side of the third color filter CF3 away from the base substrate 110 is represented by S3.

In addition, the color filter layer 130 may further include a glass substrate, a black matrix BM, a protective layer OC, an ITO conductive film, a columnar spacer, etc.

The micro lenses Lens1, Lens2 and Lens3 are located on a side of the color filter layer 130 away from the base substrate 110, and correspond one-to-one with the color filters CF1, CF2 and CF3. The so-called “correspond one-to-one” here refers to providing a corresponding micro lens on a side of each color filter away from the base substrate. The arrangement of the micro lenses Lens1 to Lens3 may be identical to the arrangement of the color filters CF1 to CF3, such as bar arrangement, dot arrangement, triangle arrangement, or mosaic arrangement, etc. In this way, each light-emitting unit and corresponding color filter and micro lens above the light-emitting unit form a light-emitting structure. The light emitted by the light-emitting unit passes through the color filter, and becomes light with the color of the color filter, which is then converged by the micro lens to improve brightness. For example, the light-emitting units EL1 to EL3 emit white light, and then the white light passes through the color filters CF1 to CF3 with different colors, so as to form light with different colors for the display panel 100.

In embodiments of the present disclosure, a surface of each of the micro lenses Lens1, Lens2, and Lens3 on a side of the micro lens away from the base substrate 110 may include a central part 170 and an edge part 180 surrounding the central part 170. The central part 170 is a flat surface parallel to the base substrate 110, and the edge part 180 is a curved surface protruding from an inside of the micro lens to an outside of the micro lens. A roughness of the central part 170 is greater than a roughness of the edge part 180. The roughness here may refer to an average value of roughnesses of the surface; alternatively, it may refer to a roughness at a certain position, such as at any position in the region or a geometric center of the region. Embodiments of the present disclosure do not limit this.

In some embodiments, a photolithographic material 190 is filled between adjacent micro lenses, so that the edge part 180 of the micro lens is covered by the photolithographic material 190. A refractive index of the photolithographic material is lower than a refractive index of the micro lens. For example, the refractive index of the photolithographic material is in a range of 1.3 to 1.6, and the refractive index of the micro lens is in a range of 1.6 to 2.1.

In a process of forming the micro lenses, a dry etching process may be added. For example, after forming a hemispherical initial micro lens, a photolithographic material layer is deposited to completely cover a surface of the initial micro lens and a planarization is performed, and then dry etching is performed on the initial micro lens and the photolithographic material layer. In the dry etching process, the roughness of the central part 170 increases due to undergoing dry etching, while the roughness of the edge part 180 remains unchanged due to being covered by the photolithographic material and not undergoing dry etching, so that the roughness of the central part 170 is greater than the roughness of the edge part 180. As shown in FIG. 1, the central part 170 of the micro lens Lens1 corresponds to a middle region of the sub-pixel SP1. As the light in the middle region of the sub-pixel SP1 is mainly emitted in the direction perpendicular to the base substrate 110, the loss of brightness of the light emitted in the middle region may be minimized by increasing the roughness of the central part 170. The roughened central part 170 may improve the viewing angle characteristics, and therefore the central part 170 may also be referred to as a viewing angle improvement region. The edge part 180 of the curved surface may converge more light to the central part 170 to enhance the brightness, and therefore the edge part 180 may also be referred to as a brightness improvement region. In addition, the micro lens provided in the present disclosure may avoid the problem of deformation caused by a compression of a cover plate on a spherical micro lens after the cover plate and the micro lens are assembled, thereby improving the stability of the micro lens.

In some embodiments, the display panel 100 may further include a planarization layer 140 (hereinafter referred to as a first planarization layer). The first planarization layer 140 is located between the color filter layer 130 and the plurality of micro lenses Lens1 to Lens3, as shown in FIG. 1. The color filter layer 130 may be covered by the first planarization layer 140.

In some embodiments, the display panel 100 may further include an inorganic layer. The inorganic layer is located between the first planarization layer 140 and the plurality of micro lenses Lens1 to Lens3.

In some embodiments, the display panel 100 may further include another planarization layer 150 (hereinafter referred to as a second planarization layer). As shown in FIG. 1, the second planarization layer 150 is located between the color filter layer 130 and the encapsulation layer 120. A thickness of the second planarization layer 150 is less than a thickness of the first planarization layer 140, and a thickness difference between any two of the plurality of color filters CF1, CF2, and CF3 is less than the thickness of the second planarization layer 150.

In some embodiments, a pixel defining layer 160 may be further provided between the base substrate 110 and the light-emitting layer EM. The pixel defining layer 160 covers an edge of the first electrode E1 (e.g. may be an anode) of each of the light-emitting units EL1 to EL3 to define an opening region OP, so that the anode E1 of each of the light-emitting units EL1 to EL3 is exposed from the opening region OP. The pixel defining layer 160 is used to define the plurality of light-emitting units EL1 to EL3 in the display panel 100.

FIG. 2 shows a schematic cross-sectional view of the micro lens shown in FIG. 1 according to an embodiment of the present disclosure.

The micro lens shown in FIG. 2 is applicable to any micro lens shown in FIG. 1. As shown in FIG. 2, a surface of the micro lens on a side of the micro lens away from the base substrate 110 includes a central part 270 and an edge part 280 surrounding the central part 270. The central part 270 is a flat surface parallel to the base substrate 110, and the edge part 280 is a curved surface protruding from an inside of the micro lens to an outside of the micro lens. The central part 270 is continuous with the edge part 280. The central part 270 has a plurality of micro bumps Bm, and only one micro bump Bm is labeled in the figure for ease of description.

In some embodiments, two adjacent micro bumps among the plurality of micro bumps Bm may be closely adjacent to each other or have a certain interval therebetween.

In some embodiments, the heights of the plurality of micro bumps Bm may be the same or different. The height of the micro bump here refers to a dimension of the micro bump Bm in the direction perpendicular to the base substrate 110. As shown in FIG. 2, a distance between the highest point and the lowest point on the surface of the micro bump Bm may be used as the dimension of the micro bump. The so-called “highest point” may be a point (also referred to as the vertex) on the surface of the micro bump Bm that is farthest from the base substrate 110, and the so-called “lowest point” may be a lowest point of a concave structure formed between adjacent micro bumps Bm. In some embodiments, the heights of the plurality of micro bumps Bm may also be different from each other. In some embodiments, the edge part 280 may also have a plurality of micro bumps. The micro bumps in the central part 270 have a height greater than that of the micro bumps in the edge part 280, so that the roughness of the central part 270 is greater than the roughness of the edge part 280.

FIG. 2 shows a cross-sectional pattern of the micro bumps in the direction perpendicular to the base substrate 110 by taking triangles as an example. However, embodiments of the present disclosure are not limited to this, and the cross-sectional pattern of the micro bumps may be set as desired, such as a rectangle, an arc-shaped, a semi-circle, a diamond or other shapes.

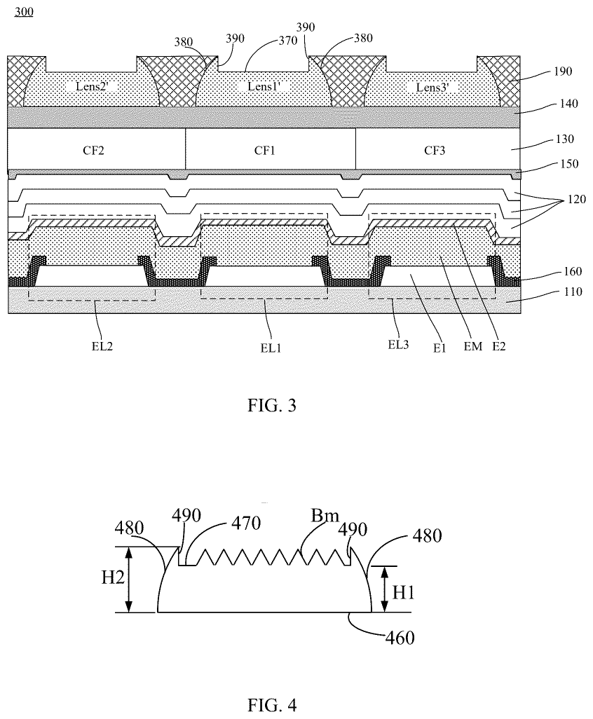

FIG. 3 shows a schematic structural diagram of a display panel according to another embodiment of the present disclosure.

The display panel 300 shown in FIG. 3 is similar to the display panel 100 shown in FIG. 1, except that the micro lens has a groove on a side of the micro lens away from the base substrate. For the sake of simplicity and clarity, the following will mainly provide detailed illustrations of the distinguishing parts.

As shown in FIG. 3, the micro lenses Lens1′, Lens2′, and Lens3′ are located on the side of the color filter layer 130 away from the base substrate 110, and correspond one-to-one with the color filters CF1, CF2 and CF3. In embodiments of the present disclosure, a surface of each of the micro lenses Lens1′, Lens2′, and Lens3′ on a side of that micro lens away from the base substrate 110 may have a groove. A bottom surface of the groove is used as the central part 370. The central part 370 is a flat surface parallel to the base substrate 110, and the edge part 380 is a curved surface protruding from an inside of the micro lens to an outside of the micro lens. The central part 370 is connected to the edge part 380 surrounding the central part 370 through a sidewall 390 of the groove. The roughness of the central part 370 is greater than the roughness of the edge part 380.

In some embodiments, in the process of forming the micro lens, the central part of the corresponding initial micro lens is patterned through a half tone mask process to form a groove. Then, a dry etching process is performed to form a micro lens with the groove, so that the roughness of the central part 370 of the micro lens is greater than the roughness of the edge part 380 of the micro lens.

FIG. 4 a schematic cross-sectional view of the micro lens shown in FIG. 3 according to an embodiment of the present disclosure.

The micro lens structure shown in FIG. 4 is applicable to any micro lens shown in FIG. 3. As shown in FIG. 4, the surface of the micro lens on the side of the micro lens away from the base substrate includes a central part 470 and an edge part 480 surrounding the central part 470. Unlike that shown in FIG. 2, the micro lens shown in FIG. 4 has a groove on the side of the micro lens away from the base substrate. A bottom surface of the groove is used as the central part 470. The central part 470 is connected to the edge part 480 through a sidewall 490 of the groove. For the micro lens shown in FIG. 4, the central part 470 is connected to the edge part 480 through the sidewall 490 of the groove.

As shown in FIG. 4, the central part 470 has a first height H1 relative to a bottom 460 of the micro lens, and the edge part 480 has a second height H2 relative to the bottom 460 of the micro lens. The first height H1 is less than the second height H2. In some embodiments, a ratio of the first height H1 to the second height H2 is in a range of 0.4 to 0.8.

Generally, an existing micro lens is hemispherical, and has a greater dimension which is comparable to the dimension of the sub-pixel (e.g. in a range of 5 μm to 10 μm). Although the hemispherical micro lens may converge light to enhance brightness, thicker micro lens materials have an absorption effect on light, resulting in a partial loss of brightness. As shown in FIG. 4, in the structure of the micro lens provided in the present disclosure, a thickness of a portion of the micro lens corresponding to the central part is reduced, and a portion of the micro lens corresponding to the edge part is kept at a higher height, so that the edge part converges more light with larger viewing angles to a middle region of the micro lens to improve brightness. As the portion of the micro lens corresponding to the central part is thinner, the transmittance of light is increased, thereby improving the brightness of the silicon-based OLED display panel.

The above description of the micro bump Bm shown in FIG. 2 also applies to the micro bump Bm provided on the central part 470, which will not be repeated here.

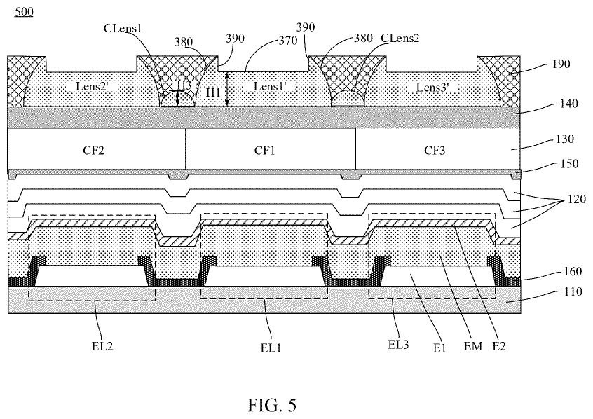

FIG. 5 shows a schematic structural diagram of a display panel according to another embodiment of the present disclosure.

The display panel 500 shown in FIG. 5 is similar to the display panel 300 shown in FIG. 3, except that a compensation micro lenses is provided between adjacent micro lenses. For the sake of simplicity and clarity, the following will mainly provide detailed illustrations of the distinguishing parts.

As shown in FIG. 5, two compensation micro lenses CLens1 and CLens2 between three adjacent micro lenses Lens1′, Lens2′, and Lens3′ are exemplarily shown. The compensation micro lens CLens1 is provided between adjacent micro lenses Lens1′ and Lens2′, and the compensation micro lens CLens2 is provided between adjacent micro lenses Lens1′ and Lens3′. However, embodiments of the present disclosure are not limited to this, and the compensation micro lenses may be provided between other adjacent micro lenses as desired.

In some embodiments, the height of the compensation micro lens is less than the height of the central part of the micro lens. For example, the height of the compensation micro lens CLens1 is less than the height of the central part of each of the micro lenses Lens1′ and Lens2′ adjacent to the compensation micro lens CLens1, and the height of the compensation micro lens CLens2 is less than the height of the central part of each of the micro lenses Lens1′ and Lens3′ adjacent to the compensation micro lens CLens2.

For example, as shown in FIG. 5, the height H3 of the compensation micro lens CLens1 is less than the height H1 of the central part 370 of the micro lens Lens1′. In this way, as the compensation micro lenses are provided between the sub-pixels, the stray light between the sub-pixels may be converged to prevent the light from adjacent sub-pixels from interfering with each other. By setting the height of the compensation micro lens to be lower than the height of the central part of the micro lens, it is possible to reduce the impact of the compensation micro lens on the main light.

In some embodiments, the height of the compensation micro lens CLens1 may be the same or different from the height of the compensation micro lens CLens2. The embodiments of the present disclosure do not limit this, as long as the height of the compensation micro lens is less than the height of the central part of the micro lens.

In some embodiments, in order to achieve better viewing angle improvement effect, the roughness of the surface of the compensation micro lens on a side of the compensation micro lens away from the base substrate 110 may be set to be less than the roughness of the central part of the micro lens.

In some embodiments, the roughness of the surface of the compensation micro lens CLens1 on the side of the compensation micro lens CLens1 away from the base substrate 110 may be the same or different from the roughness of the surface of the compensation micro lens CLens2 on the side of the compensation micro lens CLens2 away from the base substrate 110. The embodiments of the present disclosure do not limit this, as long as the roughness of the surface of the compensation micro lens on the side of the compensation micro lens away from the base substrate 110 is less than the roughness of the central part of the micro lens.

FIG. 5 shows a cross-sectional pattern of the compensation micro lens in the direction perpendicular to the base substrate 110 by taking a semi-circular shape as an example. However, the embodiments of the present disclosure are not limited to this, and the shape of the cross-sectional pattern of the compensation micro lens may be set as desired, such as a triangle, rectangle, diamond, or ellipse; alternatively, it may be an irregular shape.

In some embodiments, the compensation micro lens may also be provided in the display panel 100 shown in FIG. 1. The above description of the compensation micro lens also applies to the compensation micro lens provided in the display panel 100, and will not be repeated here.

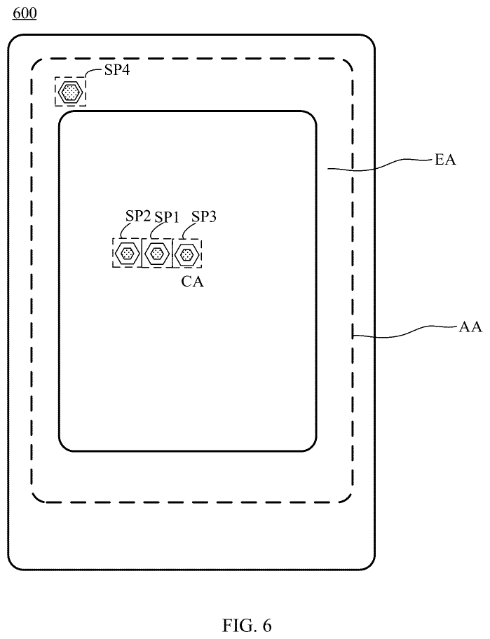

FIG. 6 shows a schematic plan view of a display panel according to embodiments of the present disclosure.

As shown in FIG. 6, the display panel 600 includes an effective display region AA. Sub-pixels SP1 to SP4 of a plurality of colors are provided in the effective display region AA. Each of the sub-pixels SP1, SP2, SP3 and SP4 is used to emit light of a corresponding color. For the convenience of description, four sub-pixels SP1, SP2, SP3 and SP4 are shown in FIG. 6. However, the embodiments of the present disclosure are not limited to this, and the display panel may have any number of sub-pixels as desired.

In some embodiments, the structures of the sub-pixels in the display panels shown in FIG. 1, FIG. 3 and FIG. 5 may be applicable to each sub-pixel shown in FIG. 6. The color of each sub-pixel is defined by the color of the color filter of that sub-pixel. For example, the color of the sub-pixel SP1 is defined by the color of the color filter CF1 of the sub-pixel SP1, the color of the sub-pixel SP2 is defined by the color of the color filter CF2 of the sub-pixel SP2, and the color of the sub-pixel SP3 is defined by the color of the color filter CF3 of the sub-pixel SP3.

In some embodiments, the sub-pixels SP1 to SP4 of the plurality of colors include a first sub-pixel SP1 having a color filter of a first color, a second sub-pixel SP2 having a color filter of a second color, a third sub-pixel SP3 having a color filter of a third color, and a fourth sub-pixel SP4 having a color filter of a first color.

In some embodiments, as shown in FIG. 6, the effective display region AA includes a central region CA and an edge region EA located on at least one side of the central region CA. The first sub-pixel SP1, the second sub-pixel SP2 and the third sub-pixel SP3 are located in the central region CA, and the fourth sub-pixel SP4 is located in the edge region EA.

In some embodiments, as shown in FIG. 6, the first sub-pixel SP1, the second sub-pixel SP2 and the third sub-pixel SP3 are adjacent to each other. However, the embodiments of the present disclosure are not limited to this, the first sub-pixel SP1, the second sub-pixel SP2 and the third sub-pixel SP3 may also be arranged at intervals.

In embodiments of the present disclosure, the fourth sub-pixel SP4 has a first color. However, the embodiments of the present disclosure are not limited to this, and the fourth sub-pixel SP4 may also have a second color or a third color.

The planar shape of the sub-pixel shown in FIG. 6 is a regular hexagon. However, the embodiments of the present disclosure are not limited to this, and the planar shape of the sub-pixel may also be other shapes, such as a rectangle, a diamond, a circle, and/or an ellipse.

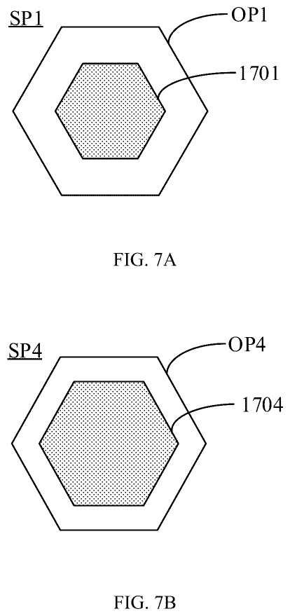

FIG. 7A and FIG. 7B show enlarged views of schematic diagrams of a first sub-pixel SP1 and a fourth sub-pixel SP4 shown in FIG. 6, respectively.

With reference to FIG. 1, FIG. 6, and FIG. 7A to FIG. B, the first sub-pixel SP1 located in the central region CA of the display panel 600 includes an opening region OP1 and a central part 1701, and the fourth sub-pixel SP4 located in the edge region EA of the display panel 600 includes an opening region OP4 and a central part 1704. The first sub-pixel SP1 and the fourth sub-pixel SP4 have the same color. In some embodiments, a ratio of an area of the central part 1701 of the first sub-pixel SP1 to an area of the opening region OP1 of the first sub-pixel SP1 is less than a ratio of an area of the central part 1704 of the fourth sub-pixel SP4 to an area of the opening region OP4 of the fourth sub-pixel SP4.

In some embodiments, the area of the opening region OP1 of the first sub-pixel SP1 may be the same or different from the area of the opening region OP4 of the fourth sub-pixel SP4. In a case that the area of the opening region OP1 of the first sub-pixel SP1 is the same as the area of the opening region OP4 of the fourth sub-pixel SP4, the area of the central part 1701 of the first sub-pixel SP1 is less than the area of the central part 1704 of the fourth sub-pixel SP4.

In some embodiments, with reference to FIG. 1, FIG. 6, and FIG. 7A to FIG. 7B, for the sub-pixels of the same colors, ratios of areas of the central parts 170 of the sub-pixels of the same colors to areas of the opening regions OP of the sub-pixels of the same colors increase from a center of the display panel 600 to an edge of the display panel 600.

As the viewing angle has to be larger in the edge region of the display panel to ensure that the light from the display panel enters human eyes, the area ratio of the central part in the edge region of the display panel is set to be larger, so as to improve the display uniformity of the display panel.

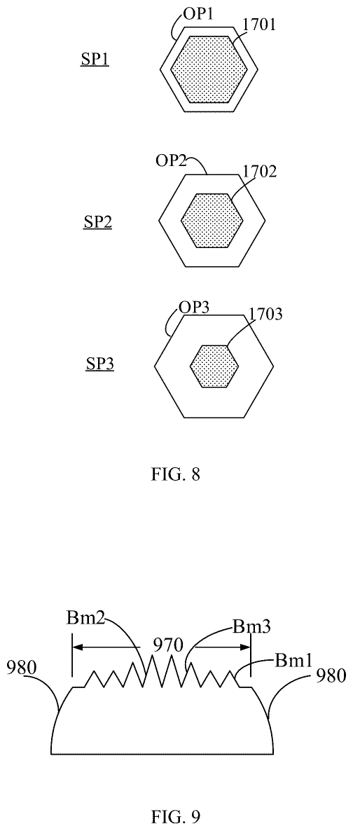

FIG. 8 shows enlarged views of schematic diagrams of a first sub-pixel SP1, a second sub-pixel SP2 and a third sub-pixel SP3 shown in FIG. 6.

With reference to FIG. 1, FIG. 6 and FIG. 8, the first sub-pixel SP1 of the first color includes an opening region OP1 and a central part 1701, the second sub-pixel SP2 of the second color includes an opening region OP2 and a central part 1702, and the third sub-pixel SP3 of the third color includes an opening region OP3 and a central part 1703.

In some embodiments, a ratio of an area of the central part of a sub-pixel of at least one color to an area of the opening region of the sub-pixel is greater than that of the sub-pixels of other colors. Taking the three sub-pixels SP1, SP2 and SP3 of different colors as an example, a relationship between the ratio of the area of the central part of the sub-pixel SP1 to the area of the opening region of the sub-pixel SP1, the ratio of the area of the central part of the sub-pixel SP2 to the area of the opening region of the sub-pixel SP2, and the ratio of the area of the central part of the sub-pixel SP3 to the area of the opening region of the sub-pixel SP3 is: Src/Sr>Sgc/Sg>Sbc/Sb, where Sr represents an area of the opening region OP1 of the first sub-pixel SP1, Sg represents an area of the opening region OP2 of the second sub-pixel SP2, Sb represents an area of the opening region OP3 of the third sub-pixel SP3, Src represents an area of the central part 1701 of the micro lens of the first sub-pixel SP1, Srg represents an area of the central part 1702 of the micro lens of the second sub-pixel SP2, and Srb represents an area of the central part 1703 of the micro lens of the third sub-pixel SP3.

In some embodiments, the area Sr of the opening region OP1 of the first sub-pixel SP1 is less than the area Sg of the opening region OP2 of the second sub-pixel SP2, and the area Sg of the opening region OP2 of the second sub-pixel SP2 is less than the area Sb of the opening region OP3 of the third sub-pixel SP3.

With reference to FIG. 6 and FIG. 8, three sub-pixels of different colors located in the central region CA are taken as an example for explanation. However, the embodiments of the present disclosure are not limited to this, and the ratios of the areas of the central parts of the sub-pixels of different colors located in the edge region EA to the areas of the opening regions of the sub-pixels of different colors located in the edge region EA also meet the above relationship.

In some embodiments, the first color is red, the second color is green, and the third color is blue. In silicon-based OLED display panels, the red sub-pixel are more prone to color shift. In the embodiments of the present disclosure, the area of the central part of the red sub-pixel is set to be larger, which may improve the color uniformity of the display panel.

FIG. 9 shows a schematic cross-sectional view of the micro lens shown in FIG. 1 according to another embodiment of the present disclosure.

The micro lens shown in FIG. 9 is similar to the micro lens shown in FIG. 2, except that the central part of the micro lens has different micro bumps. For the sake of simplicity and clarity, the following will mainly provide detailed illustrations of the distinguishing parts.

As shown in FIG. 9, the micro lens also includes a central part 970 and an edge part 980. The central part 970 has a plurality of micro bumps. The plurality of micro bumps include a first micro bump Bm1, a second micro bump Bm2, and a third micro bump Bm3. The first micro bump Bm1 is located in the edge region of the central part 970, the second micro bump Bm2 is located in the central region of the central part 970, and the third micro bump Bm3 is located between the first micro bump Bm1 and the second micro bump Bm2.

In some embodiments, a height of the second micro bump Bm2 is greater than a height of the first micro bump Bm1, so that a roughness of the central region of the central part 970 is greater than a roughness of the edge region of the central part 970.

In some embodiments, the heights of the micro bumps Bm2, Bm3 and Bm1 in the central part 970 gradually decrease from a center of the central part 970 to an edge the central part 970, that is, the height of the micro bump Bm2 is greater than the height of the micro bump Bm3, and the height of the micro bump Bm3 is greater than the height of the micro bump Bm1, so that the central part 970 has roughnesses gradually decreased from the center of the central part 970 to the edge of the central part 970. By gradient design of the heights of the micro bumps in the central part, that is, the height of the micro bump closer to the central region of the sub-pixel is higher, fine adjustment of the viewing angle characteristics of the central part may be achieved, thereby ensuring better viewing angle effect and minimum brightness loss.

In some embodiments, the dimension (also referred to as a width) of each of the micro bumps Bm1, Bm2 and Bm3 in the central part in the direction parallel to the base substrate 110 is in a range of 0.01 μm to 0.1 μm, and the dimension (also referred to as a height) of each of the micro bumps Bm1, Bm2 and Bm3 in the central part in the direction perpendicular to the base substrate 110 is in a range of 5 nm to 50 nm. The “width” of the micro bump may refer to a maximum dimension of the micro bump in the direction parallel to the base substrate, and the “height” of the micro bump may refer to a maximum dimension of the micro bump in the direction perpendicular to the base substrate.

FIG. 9 shows a cross-sectional pattern of each micro bump in the direction perpendicular to the base substrate 110 by taking a triangle as an example. However, the embodiments of the present disclosure are not limited to this. The shape of the cross-sectional pattern of the micro bump may be set as desired, such as a rectangle, an arc-shaped, a column, a semi-circle, a diamond or other shapes. In some embodiments, the micro bumps of different heights may have different shapes. For example, the cross-sectional pattern of the second micro bump Bm2 is in a shape of triangle, and the cross-sectional pattern of the first micro bump Bm1 is in a shape of semi-circle. The embodiments of the present disclosure do not limit this.

The above description of each micro bump also applies to any micro lens on the display panel shown in FIG. 1, FIG. 3 and FIG. 5, which will not be repeated here.

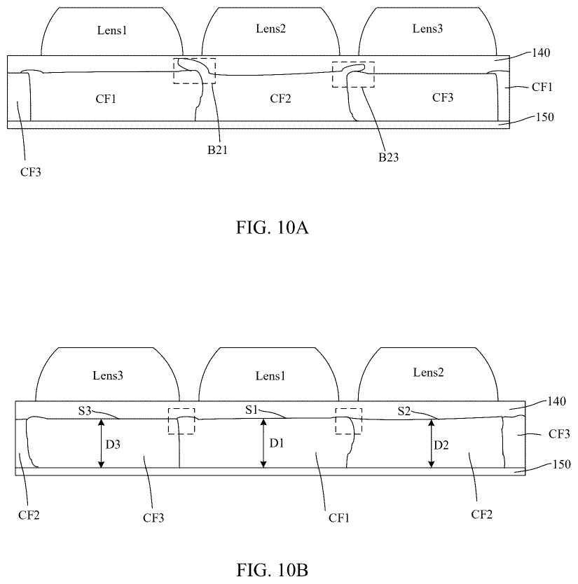

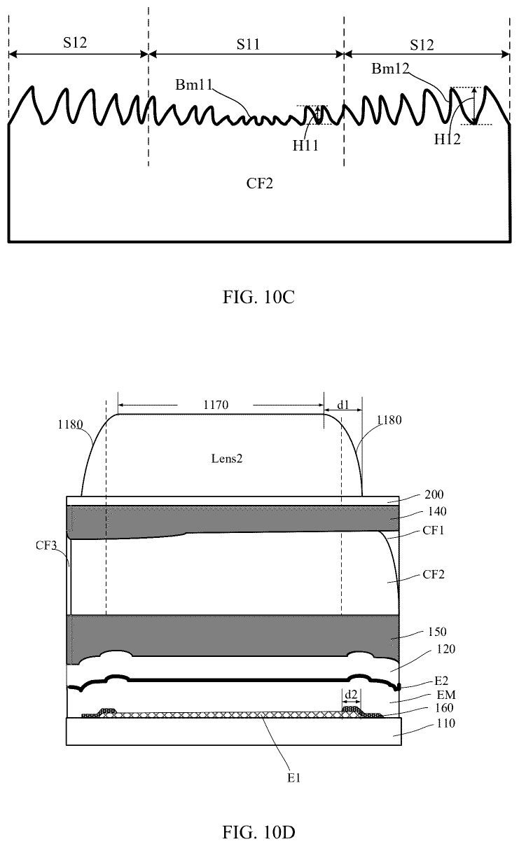

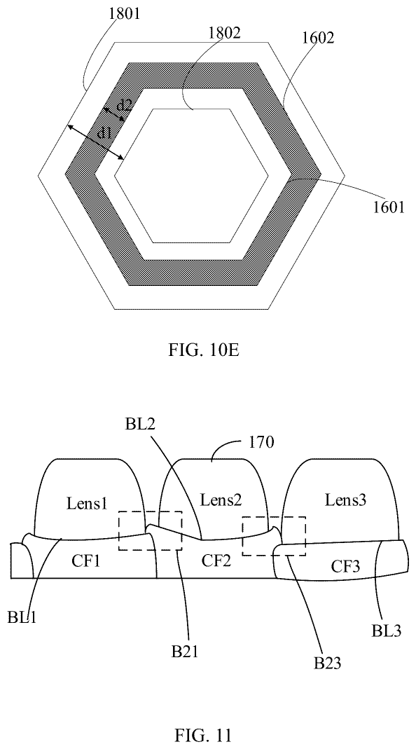

FIG. 10A shows a partial enlarged view of the display panel shown in FIG. 1 according to an embodiment of the present disclosure.

As shown in FIG. 10A, the first color filter CF1, the second color filter CF2 and third color filter CF3 in the display panel are arranged parallel to the base substrate 110, and the first color filter CF1 is located between the second color filter CF2 and the third color filter CF3. The second color filter CF2 partially covers the first color filter CF1 and the third color filter CF3, so that a part of the second color filter CF2 covering the first color filter CF1 forms a first micro bump B21, and a part of the second color filter CF2 covering the third color filter CF3 forms a second micro bump B23.

In display technology, color shift is an important indicator for evaluating the performance of the display apparatus. If the color shift viewing angle of the display apparatus is small, it is more likely to cause color shift phenomena such as redness and greenness as the viewing angle increases, which affects the visual effect. In the display device, especially in the high PPI display device such as the silicon-based organic light-emitting diode (OLEDOS, OLED on silicon), there is inevitably a height difference between the surfaces of the color filters corresponding to different pixels, resulting in the color filter having a shape similar to a bull horn in cross-section (concave in the middle and raised at the edge), and the height difference is also referred to as the bull horn height or missmatch discrepancy. Such missmatch discrepancy is usually within a range of 300 nm to 630 nm, resulting in differences in the output light effects of the color filters with different colors under lateral viewing angles. The color shift difference Au′v′<0.025 corresponds to a viewing angle of less than about 17°. In addition, the color filters are usually formed in multiple stages, and the color filter may have a shape of a concave lens when filling the gap between the previous formed color filters, resulting in the color shift at large viewing angles. To ensure that the color gamut DCI-P3 is greater than or equal to 80% while ensuring transparency and brightness, the thickness of the color filter in the weak cavity process is usually within a range of about 1.3±0.1 μm.

In some embodiments, by adopting the etch back process after forming the color filter material layer, the bull horn missmatch discrepancy may be reduced or even removed, thereby improving the flatness of the surface of the color filter layer and alleviating the problem of color shift. As shown in FIG. 10B, the bumps (also referred to as the bull horn structures) of the color filter unit CF2 on both sides of the color filter unit CF2 in the color filter material layer are substantially removed, thereby obtaining the surface of the color filter layer with a relatively high flatness. For example, the part of the color filter located in the dashed box of FIG. 10B has a substantially flat surface.

Combined with reference to FIG. 1 and FIG. 10B, the upper surfaces S1, S2, and S3 of the first color filter CF1 to the third color filter CF3 may be substantially flush with each other, for example, a height difference between the upper surfaces of various color filters may be controlled at around 100 nm. For example, the first color filter CF1, the second color filter CF2 and the third color filter CF3 may have thicknesses D1, D2, and D3, respectively, and a difference between any two of the thicknesses D1, D2, and D3 is less than 100 nm. For example, D1, D2, and D3 may be in a range of 1.1 μm to 1.3 μm. In some embodiments, D2<D1<D3. In some embodiments, the difference between D1 and D2 is in a range of 10 nm to 30 nm, and the difference between D1 and D3 is in a range of 20 nm to 50 nm. The so-called thickness of the color filter here may refer to an average thickness of the color filter, or refer to a thickness of the color filter at a certain position, such as a thickness at a geometric center of the color filter, or refer to a maximum or minimum thickness of the color filter. In some embodiments, a ratio of the thickness of the first planarization layer 140 to the width of the overlapping portion between any two of the plurality of color filters CF1 to CF3 is in a range of 1 to 1.8. That is to say, the thickness of the first planarization layer 140 is greater than the width of the overlapping portion between any two of the color filters CF1 to CF3, and less than 1.8 times the width of the overlapping portion.

FIG. 10C shows a partial enlarged view of a surface of a color filter shown in FIG. 10B.

As shown in FIG. 10C, taking the second color filter CF2 as an example, the surface S1 of the second color filter CF2 on a side of the second color filter CF2 away from the base substrate 110 includes a central region S11 and an edge region S12 surrounding the central region S11.

In some embodiments, the central region S11 has a plurality of micro bumps Bm11, and the edge region S12 has a plurality of micro bumps Bm12. As shown in FIG. 10C, a height H11 of the micro bump Bm11 is less than a height H12 of the micro bump Bm12, causing a roughness of the central region S11 to be less than a roughness of the edge region S12. In some embodiments, the height H11 of the micro bump Bm11 is less than 5 nm, and the height H12 of the micro bump Bm12 is greater than 5 nm.

In some embodiments, the heights of the plurality of micro bumps on the surface S1 of the second color filter CF2 on the side of the second color filter CF2 away from the base substrate 110 increase from the center of the second color filter CF2 to the edge of the second color filter CF2, so that the surface S1 of the second color filter CF2 on the side of the second color filter CF2 away from the base substrate 110 has roughnesses gradually increased from the center of the second color filter CF2 to the edge of the second color filter CF2. The first color filter CF1 and the third color filter CF3 have similar structures, which will not be elaborated here.

FIG. 10D shows a partial enlarged view of the display panel shown in FIG. 10B according to an embodiment of the present disclosure.

As shown in FIG. 10D, a green sub-pixel is taken as an example, the sub-pixel includes a color filter CF2, a micro lens Lens2, and a light-emitting unit having a first electrode E1, a second electrode E2, and a light-emitting layer EM. The micro lens Lens2 may have the structure described above with reference to FIG. 9, that is, the heights of the micro bumps of the central part 1170 of the micro lens Lens2 gradually decrease from the center of the central part 1170 to the edge of the central part 1170, so that the central part 1170 has roughnesses gradually decreased from the center of the central part 1170 to the edge of the central part 1170. The color filter CF2 may have the structure described above with reference to FIG. 10C, that is, the surface of the color filter CF2 on the side of the color filter CF2 away from the base substrate 110 has roughnesses gradually increased from the center region of the color filter CF2 to the edge region of the color filter CF2. In some embodiments, the height of the micro bump may be used to define the central region of the color filter and the edge region of the color filter. For example, the height of the micro bump in the central region of the color filter is less than 5 nm, and the height of the micro bump in the edge region of the color filter is in a range of 5 nm to 50 nm. For example, as shown in FIG. 10D, the boundary between the center and edge regions of the color filter is shown by two dashed lines. The region between the two dashed lines is the central region of the color filter, and the region on the side of the two dashed lines away from the central region is the edge region of the color filter. In some embodiments, as shown in FIG. 10D, a projection of a boundary between the central region of the color filter CF2 and the edge region of the color filter CF2 on the base substrate 110 is within a projection of the edge part 1180 of the micro lens Lens2 on the base substrate 110.

As the roughness of the edge region of the color filter is greater than the roughness of the center region of the color filter, the roughness of the edge region is higher, and light is easily scattered, which is not conducive to brightness improvement in some usage scenes. In the present disclosure, the roughness of the surface of the micro lens is complementary with the roughness of the surface of the color filter. For example, the roughness of the center of the central part 1170 of the micro lens Lens2 is high and the roughness of the edge of the central part 1170 of the micro lens Lens2 is low, while the roughness of the center of the surface of the color filter CF2 below the micro lens Lens2 is low, and the roughness of the edge of the surface of the color filter CF2 below the micro lens Lens2 is high, that is, the roughness settings of the two are opposite. The roughnesses of the surfaces of the two are complementary with each other, thereby improving the display uniformity.

In embodiments of the present disclosure, a first planarization layer 140 is provided between the micro lens Lens2 and the color filter CF2. However, the embodiments of the present disclosure are not limited to this. In other embodiments, the micro lens Lens2 may be in contact with the color filter CF2.

In some embodiments, an inorganic layer 200 may be provided between the first planarization layer 140 and the micro lens Lens2.

In other embodiments, the micro lens shown in FIG. 10D may have the structure or combination of any micro lens mentioned in the aforementioned embodiments of the present disclosure. The green color filter CF2 shown in FIG. 10D is only shown as an example, and the red color filter and the blue color filter in the embodiments of the present disclosure may have similar structures, which is not limited by the present disclosure.

Continued with reference to FIG. 10D, the sub-pixel further includes a pixel defining layer 160 covering an edge of the first electrode E1. In some embodiments, the edge part 1180 has a first projection in the direction perpendicular to the base substrate 110, and a part of the pixel defining layer 160 covering the anode E1 has a second projection in the direction perpendicular to the base substrate 110. The second projection falls within the first projection. Combined with reference to FIG. 10D and FIG. 10E, the first projection includes a first edge 1801 and a second edge 1802. The first edge 1801 is an outer edge of the first projection and the second edge 1802 is an inner edge of the first projection. The second projection includes a third edge 1601 and a fourth edge 1602. The third edge 1601 is an inner edge of the second projection and the fourth edge 1602 is an outer edge of the second projection.

In embodiments of the present disclosure, the shape of each of the first edge 1801, the second edge 1802, the third edge 1601 and the fourth edge 1602 is a regular hexagon. A distance between the first edge 1801 and the second edge 1802 is d1, and a distance between the third edge 1601 and the fourth edge 1602 is d2, where d1 is greater than d2, causing the second projection to fall within the first projection, thereby ensuring the convergence of the edge light. The “distance” between two edges may be the minimum or maximum value of the distance between the two edges. In the embodiments of the present disclosure, the first projection and the second projection may have a shape of band with an equal width, as shown in FIG. 10E, so that the width of the band is the same, that is to say, a distance between the inner edge of the projection and the outer edge of the projection is the same at all positions.

In other embodiments, each edge may also have the other shape, such as rectangle, circle, or irregular shape, as long as an orthographic projection of the part of the pixel defining layer covering the anode on the base substrate falls within an orthographic projection of the edge part on the base substrate. The present disclosure does not limit this.

FIG. 11 shows a partial enlarged view of a display panel according to another embodiment of the present disclosure.

Similar to that shown in FIG. 10, the display substrate shown in FIG. 11 includes a first color filter CF1, a second color filter CF2, a third color filter CF3, and a first micro lens Lens1, a second micro lens Lens2 and a third micro lens Lens3 above the color filters.

Unlike that shown in FIG. 10A, the micro lenses Lens1, Lens2, and Lens3 shown in FIG. 11 are in contact with the corresponding color filters CF1, CF2, and CF3. As shown in FIG. 11, the surface of the micro lens Lens1 in contact with the color filter CF1 is represented by BL1. The surface of the micro lens Lens2 in contact with the color filter CF2 is represented by BL2. The surface of the micro lens Lens3 in contact with the color filter CF3 is represented by BL3.

In embodiments of the present disclosure, as the thicknesses of the color filters CF1 to CF3 are different, a height difference exists between any two of the respective surfaces BL1 to BL3 of the micro lenses Lens1 to Lens3 in contact with the color filters. For example, the color filter CF2 may be a green color filter, and the thickness of the color filter CF2 is greater than the thickness of the color filter CF1 and the thickness of the color filter CF3, and the color filter CF2 has a bull horn structure. Therefore, the bottom surface BL2 of the micro lens Lens2 in the direction perpendicular to the base substrate is higher than the bottom surface BL2 of the micro lens Lens1 and the bottom surface BL3 of the micro lens Lens1. Due to the introduction of dry etching process in the process of forming the micro lenses Lens1 to Lens3, the hemispherical micro lenses are flattened, causing the central parts 170 of the micro lenses Lens1, Lens2 and Lens3 to be located in a same plane, thereby avoiding the problem of uneven display caused by directly providing the hemispherical micro lenses on the color filter, which results in the light output surfaces of the micro lenses not being in the same horizontal plane.

In some embodiments, a planarization layer may further be provided between the micro lens of each sub-pixel and the color filter to further reduce the adverse effects caused by the bull horn structure of the color filter.

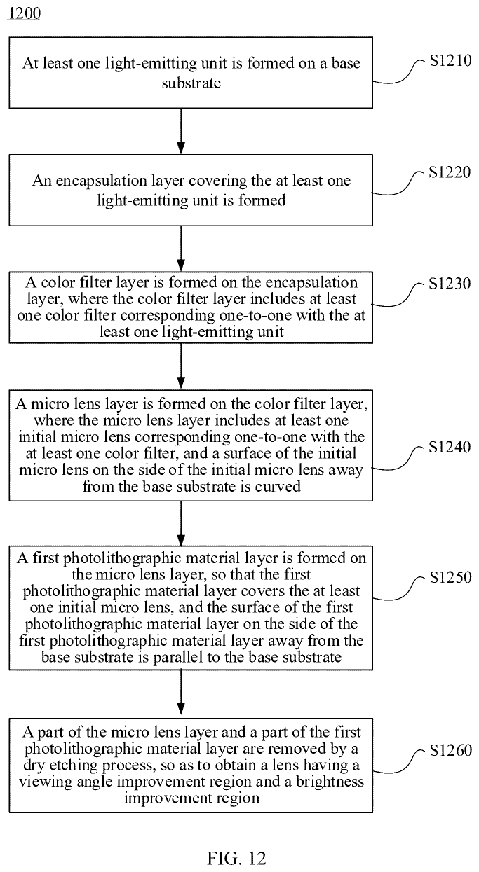

FIG. 12 shows a flowchart of a method of manufacturing a display panel according to embodiments of the present disclosure.

As shown in FIG. 12, the method 1200 of manufacturing the display panel includes step S1210 to step S1260.

In step S1210, at least one light-emitting unit is formed on a base substrate.

In step S1220, an encapsulation layer covering the at least one light-emitting unit is formed.

In step S1230, a color filter layer is formed on the encapsulation layer, where the color filter layer includes at least one color filter corresponding one-to-one with the at least one light-emitting unit.

In step S1240, a micro lens layer is formed on the color filter layer, where the micro lens layer includes at least one initial micro lens corresponding one-to-one with the at least one color filter, and a surface of the initial micro lens on the side of the initial micro lens away from the base substrate is a curved surface.

In step S1250, a first photolithographic material layer is formed on the micro lens layer, so that the first photolithographic material layer covers the at least one initial micro lens, and the surface of the first photolithographic material layer on the side of the first photolithographic material layer away from the base substrate is parallel to the base substrate.

In step 1260, a part of the micro lens layer and a part of the first photolithographic material layer are removed by a dry etching process to obtain a micro lens having a central part and an edge part.

In some embodiments, step S1260 may include the following steps: performing dry etching on the micro lens layer and the first photolithographic material layer to obtain a micro lens having a central part and an edge part, where the central part is continuous with the edge part.

In other embodiments, step S1260 may include the following steps: forming a groove in the first photolithographic material layer above each micro lens by a half tone mask process to obtain a patterned first photolithographic material layer; performing a dry etching on the patterned first photolithographic material layer and the micro lens layer to obtain a micro lens having a groove, where a bottom surface of the groove is used as the central part, and the central part is connected to the edge part through a sidewall of the groove.

In some embodiments, before performing step S1240, the following steps may be performed: forming a second photolithographic material layer on the color filter layer; and removing the second photolithographic material layer and a part of the color filter layer by a dry etching process to flatten the color filter layer.

In some embodiments, before performing step S1240, the following steps may be performed: forming a planarization layer on the color filter layer. In some embodiments, after forming a planarization layer on the color filter layer, an inorganic layer may be formed on the planarization layer.

In some embodiments, step S1240 may include the following steps: depositing an organic micro lens material on the color filter layer; removing a part of the micro lens material by exposing and developing to obtain a plurality of columnar structures; transforming each of the plurality of columnar structures into a hemispherical structure by hot reflux process; curing the hemispherical structure to obtain an initial micro lens. In some embodiments, in the hot reflux process, when heating the columnar structure, due to the organic material of the columnar structure having a certain fluidity at a certain temperature, the columnar structure naturally forms a hemispherical micro lens under the action of gravity.

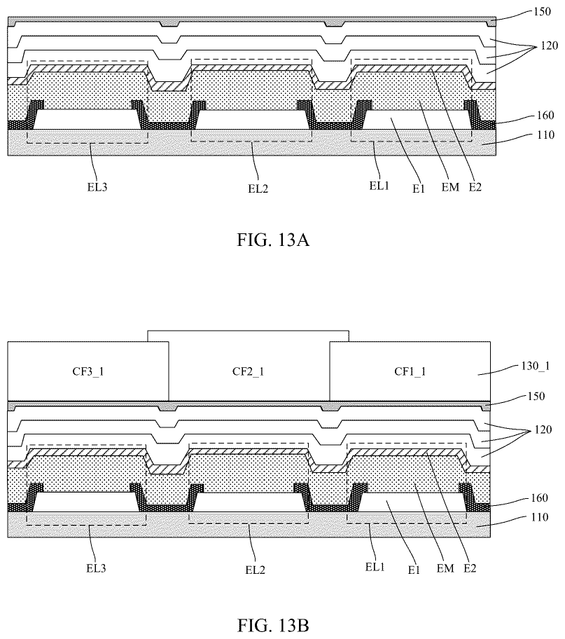

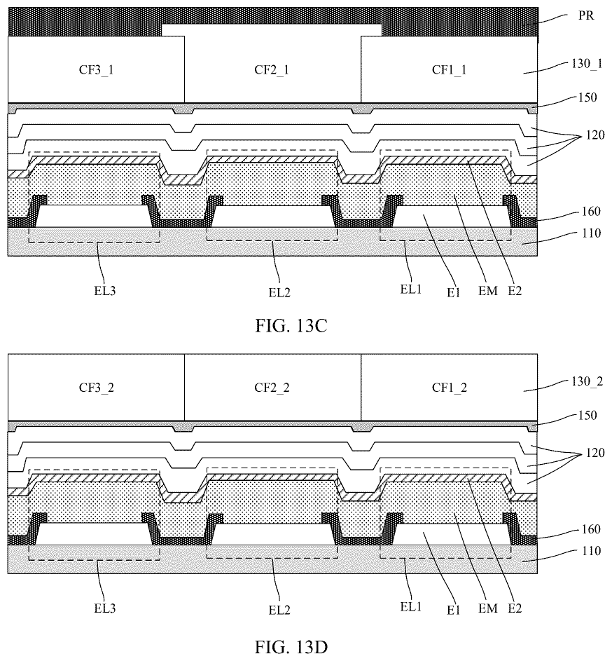

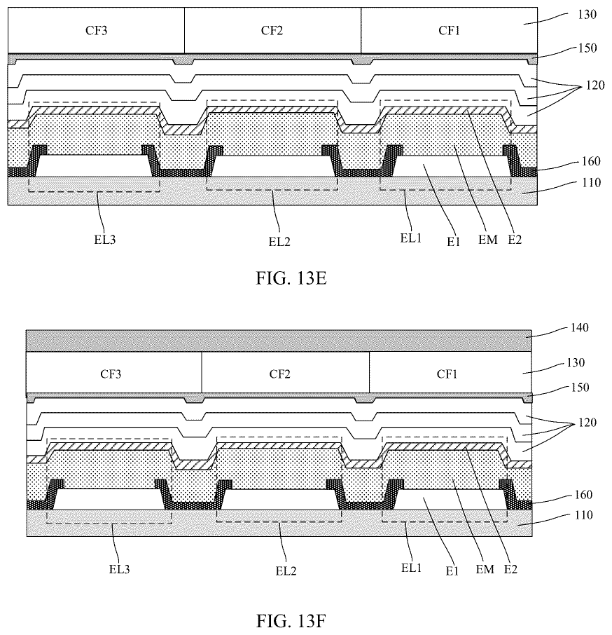

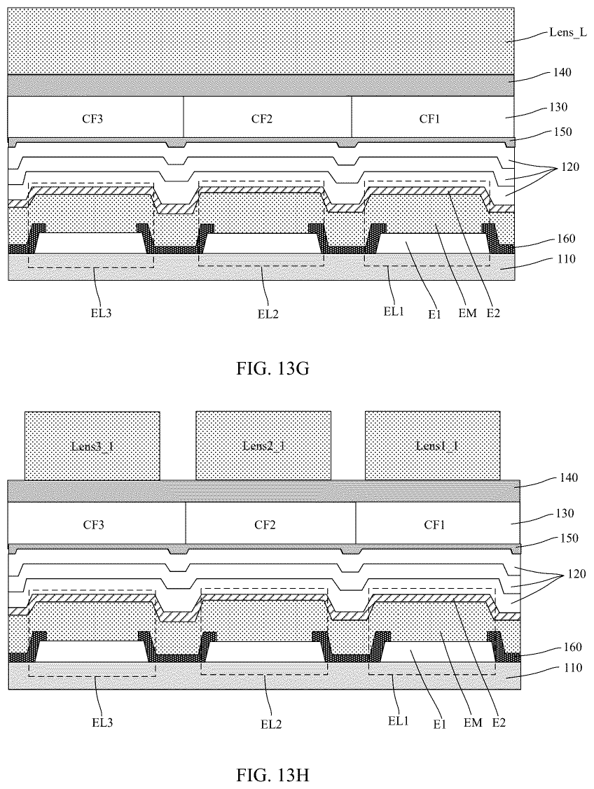

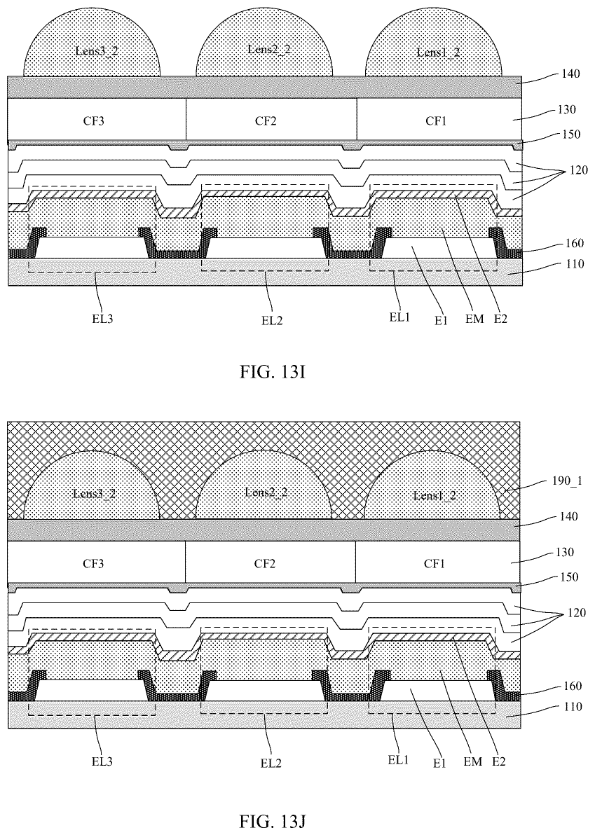

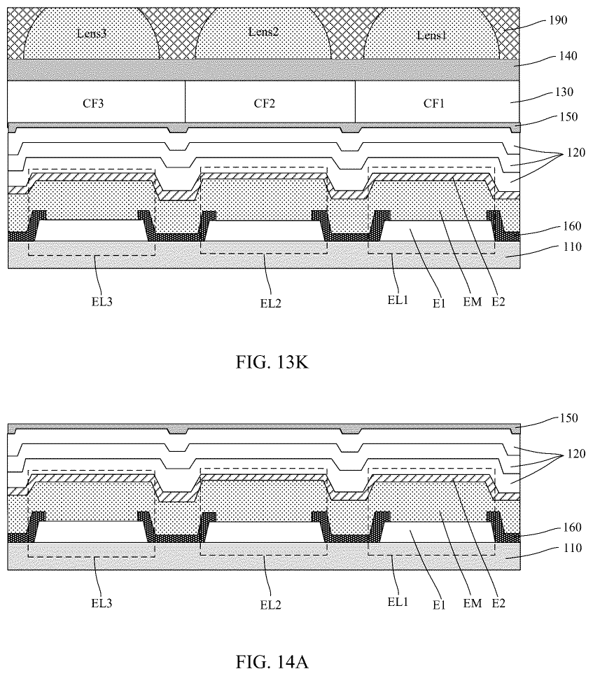

FIG. 13A to FIG. 13K show a process of manufacturing a display panel according to an embodiment of the present disclosure.

As shown in FIG. 13A, a plurality of light-emitting units EL1 to EL3, a pixel defining layer 160, an encapsulation layer 120 and a second planarization layer 150 are sequentially formed on the base substrate 110.

Then, a color filter material layer 130_1 is formed on the structure shown in FIG. 13A, obtaining the structure shown in FIG. 13B. As shown in FIG. 13B, the color filter material layer 130_1 may include a plurality of color filter units CF1_1, CF2_1 and CF3_1 corresponding one-to-one with the plurality of light-emitting units EL1 to EL3. For example, the plurality of color filter units CF_1, CF2_1 and CF3_1 may be made of red color filter material, green color filter material and blue color filter material, respectively. The green color filter unit CF2_1 covers a part of the red color filter unit CF1_1 and a part of the blue color filter unit CF3_1 on both sides of the green color filter unit CF2_1, so as to form bumps on both sides of the color filter unit CF2_1.

Next, as shown in FIG. 13C, a photosensitive material PR (also referred to as a second photolithographic material layer) is coated on the color filter material layer 130_1, so that the color filter material layer 130_1 is completely covered by the photosensitive material PR. A thickness of the photosensitive material PR is greater than heights of the bumps of the color filter unit CF2_1 on both sides of the color filter unit CF2_1 in the color filter material layer 130_1, so that the photosensitive material PR may completely cover the color filter material layer 130_1 for subsequent etching. An etching selection ratio of the photosensitive material PR to the material of the color filter material layer 130_1 is substantially 1:1, so that in the subsequent etching process, an etching rate of each color filter unit in the color filter material layer is substantially equal to an etching rate of the photosensitive material. In practical operations, due to the difference between any two of the materials of the color filter units, there is a slight difference between any two of the etching rates of the color filter units, and this substantially does not affect the expected flatness of the entire color filter material layer.

Next, as shown in FIG. 13D, etching is performed on the photosensitive material PR and the color filter material layer 130_1 covered by the photosensitive material PR shown in FIG. 13C until a thickness of the color filter material layer 130_1 is reduced to a first thickness, thereby obtaining the color filter material layer 130_2 with the first thickness. The first thickness may be in a range of 1.4 μm=0.1 μm.

Next, as shown in FIG. 13E, the color filter material layer 130_2 with the first thickness is over-etched until the thickness of the color filter material layer 130_2 is further reduced to a second thickness, thereby obtaining the color filter layer 130 with the second thickness. The color filter layer 130 has a structure as described in any of the above embodiments. In some embodiments, the second thickness may be in a range of 1.2 μm±0.1 μm. By performing over-etching, residual photoresist may be removed and the flatness of the color filter layer may be further improved. The etching depth may be set as desired to obtain the desired surface structure of the color filter layer. For example, the bumps (also referred to as the bull horn structures) on both sides of the color filter unit CF2_1 in the color filter material layer may be completely removed, thereby obtaining the surface of the color filter layer with a relatively high flatness as shown in FIG. 10B.

Next, as shown in FIG. 13F, the first planarization layer 140 is formed on the color filter layer 130.

Next, as shown in FIG. 13G, the organic micro lens material is deposited on the first planarization layer 140 to obtain the micro lens material layer Lens_L. Then, a part of the micro lens material layer Lens_L is removed by exposing and developing, thereby obtaining the columnar structures Lens1_1, Lens2_1 and Lens3_1 as shown in FIG. 13H.

Then, a hot reflux process is performed on the columnar structures Lens1_1, Lens2_1 and Lens3_1 as shown in FIG. 13H, so that each of the columnar structures Lens1_1, Lens2_1 and Lens3_1 forms a hemispherical structure under the action of gravity naturally.

Then, the hemispherical structure is cured to obtain the initial micro lenses Lens1_2, Lens2_2 and Lens3_2 as shown in FIG. 13I. The initial micro lenses Lens1_2, Lens2_2 and Lens3_2 correspond to the first color filter CF1, the second color filter CF2, and the third color filter CF3, respectively. In some embodiments, the surface of each of the initial micro lenses Lens1_2, Lens2_2 and Lens3_2 on the side of each of the initial micro lenses Lens1_2, Lens2_2 and Lens3_2 away from the base substrate 110 is a curved surface.

Next, as shown in FIG. 13J, a first photolithographic material layer 190_1 is formed on the initial micro lenses Lens1_2, Lens2_2 and Lens3_2. The surface of the first photolithographic material layer 190_1 on a side of the first photolithographic material layer 190_1 away from the base substrate 110 is parallel to the base substrate 110.

Then, a dry etching process is performed on the first photolithographic material layer 190_1 and the initial micro lenses Lens1_2, Lens2_2 and Lens3_2 to remove a part of the first photolithographic material layer 190_1 and a part of each of the initial micro lenses Lens1_2, Lens2_2 and Lens3_2, thereby obtaining the structure shown in FIG. 13K. That is, the display panel structure shown in FIG. 1 is obtained, where the micro lenses Lens1, Lens2, and Lens3 each have a flat central part and a curved edge part. Due to the dry etching process, the roughness of the central part is greater than that of the edge part.

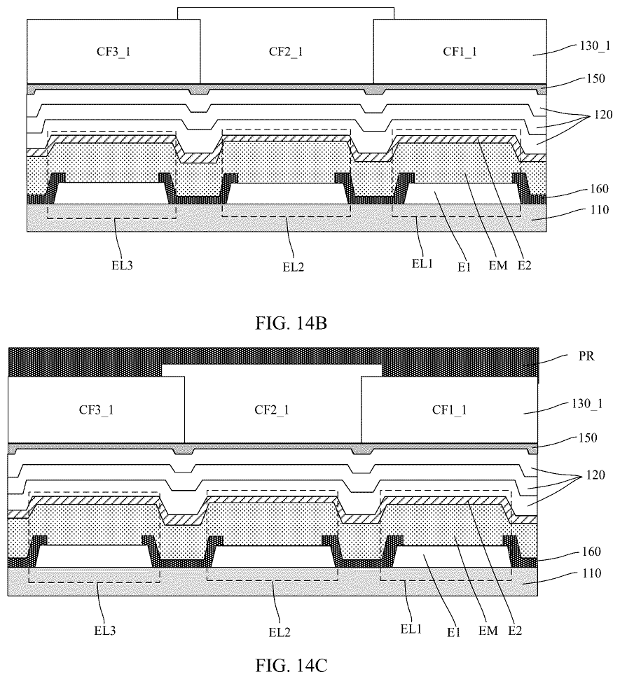

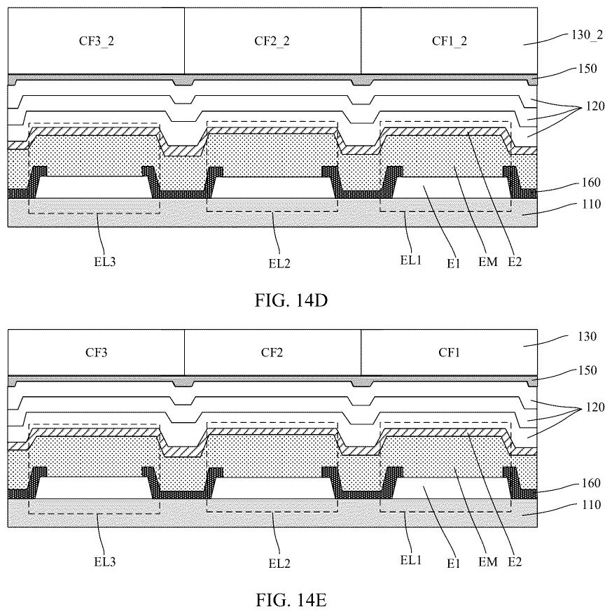

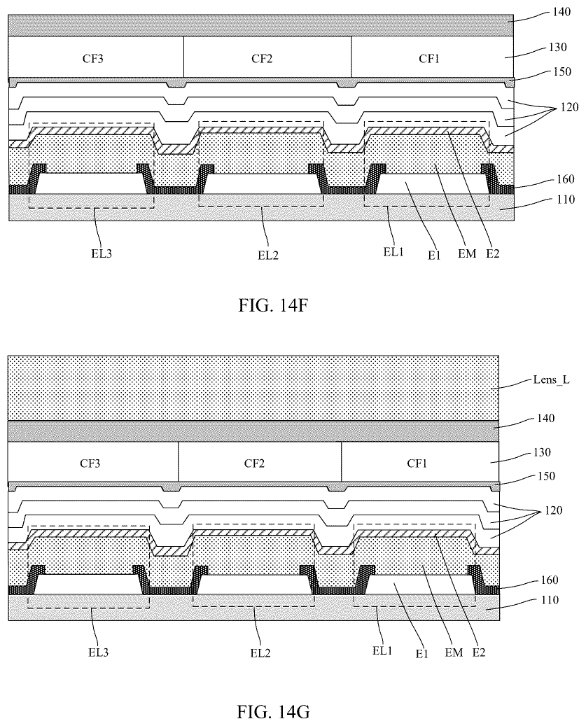

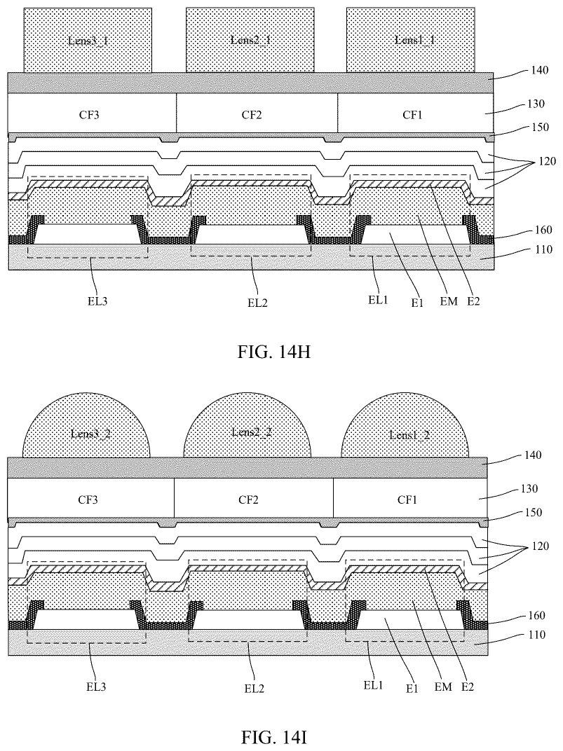

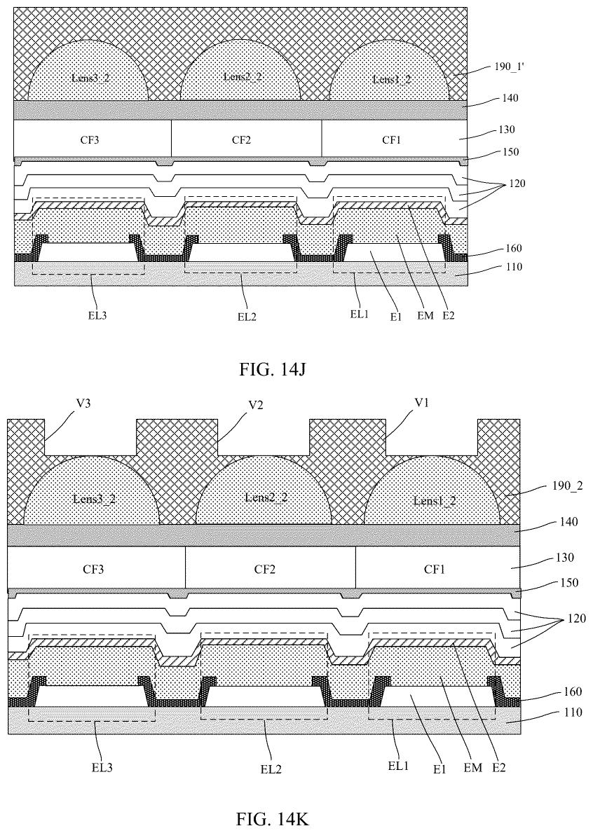

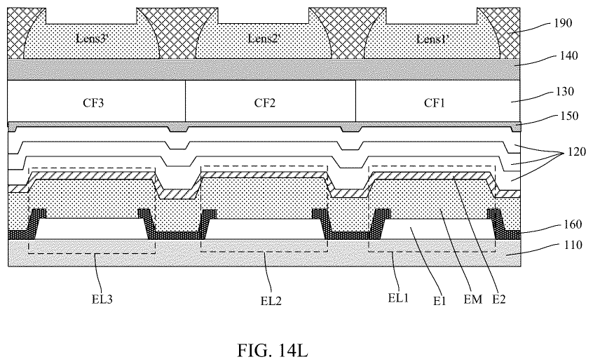

FIG. 14A to FIG. 14L show a process of manufacturing a display panel according to another embodiment of the present disclosure.

The process of manufacturing the display panel shown in FIG. 14A to FIG. 14I is the same as the process of manufacturing shown in FIG. 13A to FIG. 13I, which will not be repeated here.

Next, as shown in FIG. 14J, a first photolithographic material layer 190_1′ is formed on the structure shown in FIG. 14I. The first photolithographic material layer 190_1′ covers the initial micro lenses Lens1_2, Lens2_2 and Lens3_2. The thickness of the first photolithographic material layer 190_1′ may be the same or different from the thickness of the first photolithographic material layer 190_1 shown in FIG. 13J.

Next, a half tone mask process is performed on the first photolithographic material layer 190_1′ shown in FIG. 14J to form a groove in the first photolithographic material layer 190_1′ above each of the initial micro lenses Lens1_2, Lens2_2 and Lens3_2. For example, a groove V1 is formed above the initial micro lens Lens1_2, a groove V2 is formed above the initial micro lens Lens2_2, and a groove V3 is formed above the initial micro lens Lens3_2, thereby obtaining a patterned first photolithographic material layer 190_2 as shown in FIG. 14K. The shapes and dimensions of the grooves V1 to V3 may be provided as desired, for example, providing the shapes and dimensions of the grooves according to the dimension of the central part to be formed.

Then, dry etching is performed on the patterned first photolithographic material layer 190_2 and each of the initial micro lenses Lens1_2, Lens2_2 and Lens3_2 to obtain the structure shown in FIG. 14L, that is, obtaining a display panel structure as shown in FIG. 3 or FIG. 5. Each of the micro lenses Lens1′, Lens2′ and Lens3′ in the display panel has a groove. A bottom surface of the groove is used as the central part. The central part is connected to the edge part through a sidewall of the groove. Due to the dry etching process, the roughness of the central part of each micro lens is greater than that of the edge part of each micro lens.

Those skilled in the art may understand that embodiments described above are exemplary, and those skilled in the art may improve them. The structures described in various embodiments may be freely combined without structural or principle conflicts.

After elaborating on the preferred embodiments of the present disclosure, those skilled in the art may clearly understand that various changes and approaches may be made without departing from the scope and spirit of the accompanying claims, and the present disclosure is not limited to the implementation methods of the exemplary embodiments cited in the specification.

1. A display panel, comprising:
a base substrate; and
one or more sub-pixels on the base substrate,
wherein each of the one or more sub-pixels comprises:
a light-emitting unit having a first electrode, a second electrode and a light-emitting layer between the first electrode and the second electrode, wherein the first electrode is located between the light-emitting layer and the base substrate;
an encapsulation layer covering the light-emitting unit;
a color filter on a side of the encapsulation layer away from the base substrate; and
a micro lens on a side of the color filter away from the base substrate,
wherein a surface of the micro lens on a side of the micro lens away from the base substrate comprises a central part and an edge part surrounding the central part, the central part is a flat surface parallel to the base substrate, the edge part is a curved surface protruding from an inside of the micro lens to an outside of the micro lens, and a roughness of the central part is greater than a roughness of the edge part.

2. The display panel of claim 1, wherein the central part is continuous with the edge part.

3. The display panel of claim 1, wherein the micro lens has a groove on the side of the micro lens away from the base substrate, a bottom surface of the groove serves as the central part, and the central part is connected to the edge part through a sidewall of the groove.

4. The display panel of claim 3, wherein the central part has a first height relative to a bottom of the micro lens, the edge part has a second height relative to the bottom of the micro lens, and a ratio of the first height to the second height is in a range of 0.4 to 0.8.

5. The display panel of claim 1, further comprising a compensation micro lens between adjacent micro lenses, wherein a height of the compensation micro lens is less than a height of the central part of the micro lens.

6. The display panel of claim 5, wherein a roughness of a surface of the compensation micro lens on a side of the compensation micro lens away from the base substrate is less than the roughness of the central part.

7. The display panel of claim 1, wherein each of the central part and the edge part has a plurality of micro bumps, and the plurality of micro bumps of the central part have a height greater than a height of the plurality of micro bumps of the edge part, so that the roughness of the central part is greater than the roughness of the edge part.

8. The display panel of claim 7, wherein the plurality of micro bumps in a central region of the central part have a height greater than a height of the plurality of micro bumps in an edge region of the central part, so that a roughness of the central region of the central part is greater than a roughness of the edge region of the central part.

9. The display panel of claim 8, wherein the plurality of micro bumps of the central part have heights decreased from a center of the central part to an edge of the central part, so that the central part has roughnesses decreased from the center of the central part to the edge of the central part.

10. The display panel of claim 7, wherein a cross-section of one of the plurality of micro bumps of the central part in a direction perpendicular to the base substrate is in a shape of triangle, arc or rectangle.

11. The display panel of claim 7, wherein the plurality of micro bumps of the central part have a dimension in a range of 0.01 μm to 0.1 μm in a direction parallel to the base substrate, and the plurality of micro bumps of the central part have a dimension in a range of 5 nm to 50 nm in a direction perpendicular to the base substrate.

12. The display panel of claim 1, wherein a roughness of a central region of a surface of the color filter on the side of the color filter away from the base substrate is less than a roughness of an edge region of the surface of the color filter on the side of the color filter away from the base substrate.

13. The display panel of claim 12, wherein the surface of the color filter on the side of the color filter away from the base substrate has roughnesses increased from a center of the color filter to an edge of the color filter.

14. The display panel of claim 12, wherein the surface of the color filter on the side of the color filter away from the base substrate has micro bumps, the micro bumps in a central region of the color filter have a height less than 5 nm, and the micro bumps in an edge region of the color filter have a height in a range of 5 nm to 50 nm.

15. The display panel of claim 14, wherein a projection of a boundary between the central region of the color filter and the edge region of the color filter on the base substrate is within a projection of the edge part of the micro lens on the base substrate.

16. The display panel of claim 1, wherein each of the one or more sub-pixels further comprises a pixel defining layer between the base substrate and the light-emitting layer of the light-emitting unit, and the pixel defining layer covers an edge of the first electrode of the light-emitting unit to define an opening region, such that a part of the first electrode of the light-emitting unit is exposed from the opening region.

17. The display panel of claim 16, wherein the edge part has a first projection in a direction perpendicular to the base substrate, and a part of the pixel defining layer covering the first electrode has a second projection in the direction perpendicular to the base substrate, and wherein a distance between an inner edge of the first projection and an outer edge of the first projection is greater than a distance between an inner edge of the second projection and an outer edge of the second projection.

18. The display panel of claim 16, wherein the one or more sub-pixels comprise a plurality of sub-pixels of a plurality of colors, and a color of each of the plurality of sub-pixels is defined by a color of the color filter of the each of the plurality of sub-pixels; and
wherein a ratio of an area of the central part of at least one of the plurality of sub-pixels having at least one color to an area of the opening region of the at least one of the plurality of sub-pixels is greater than a ratio of an area of the central part of any other one of the plurality of sub-pixels having any other color to an area of the opening region of the any other one of the plurality of sub-pixels;
wherein the plurality of sub-pixels of the plurality of colors comprise a first sub-pixel having a color filter of a first color, a second sub-pixel having a color filter of a second color, and a third sub-pixel having a color filter of a third color;
wherein Src/Sr>Sgc/Sg>Sbc/Sb, Sr represents an area of an opening region of the first sub-pixel, Sg represents an area of an opening region of the second sub-pixel, Sb represents an area of an opening region of the third sub-pixel, Src represents an area of the central part of the micro lens of the first sub-pixel, Srg represents an area of the central part of the micro lens of the second sub-pixel, and Srb represents an area of the central part of the micro lens of the third sub-pixel;
wherein Sr<Sg<Sb;
wherein the first color is red, the second color is green, and the third color is blue;
wherein for sub-pixels of same colors, a ratio of an area of the central part of any one of the sub-pixels of the same colors in a central region of the display panel to an area of the opening region of the any one of the sub-pixels of the same colors in the central region of the display panel is less than a ratio of an area of the central part of any one of the sub-pixels of the same colors in an edge region of the display panel to an area of the opening region of the any one of the sub-pixels of the same colors in the edge region of the display panel;
wherein for the sub-pixels of the same colors, ratios of areas of the central parts of the sub-pixels of the same colors to areas of the opening regions of the sub-pixels of the same colors increase from a center of the display panel to an edge of the display panel;
wherein the central parts of the micro lenses of sub-pixels of different colors are located in a same plane;
wherein the micro lens of the sub-pixel is in contact with the color filter of the sub-pixel; and
wherein bottom surfaces of the micro lenses of the sub-pixels of different colors have a height difference in the direction perpendicular to the base substrate; and wherein the micro lens is in contact with the color filter through the bottom surface of the micro lens.

19-26. (canceled)

27. The display panel of claim 1, further comprising a planarization layer between the color filter of each of the one or more sub-pixels and the micro lens of each of the one or more sub-pixels;
wherein a photolithographic material is filled between adjacent micro lenses such that the edge part of the micro lens is covered by the photolithographic material;
wherein a refractive index of the photolithographic material is less than a refractive index of the micro lens; and
wherein the refractive index of the photolithographic material is in a range of 1.3 to 1.6, and the refractive index of the micro lens is in a range of 1.6 to 2.1.

28. (canceled)

29. (canceled)

30. (canceled)

31. A display panel, comprising:
a base substrate; and
one or more sub-pixels on the base substrate,
wherein each of the one or more sub-pixels comprises:
a light-emitting unit having a first electrode, a second electrode, and a light-emitting layer between the first electrode and the second electrode, wherein the first electrode is located between the light-emitting layer and the base substrate; and
a micro lens on a side of the light-emitting unit away from the base substrate,
wherein a surface of the micro lens on a side of the micro lens away from the base substrate comprises a central part and an edge part surrounding the central part, the central part is a flat surface parallel to the base substrate, and the edge part is a curved surface protruding from an inside of the micro lens to an outside of the micro lens; and
wherein each of the central part and the edge part has a plurality of micro bumps, and the plurality of micro bumps of the central part have a height greater than a height of the plurality of micro bumps of the edge part.

32-38. (canceled)
